(19) United States
(12) Patent Application Publication
(10) Pub. No.: US 2009/0150095 A1
(43) Pub. Date: Jun. 11, 2009

(54) Ultrasonic Method For Detecting Banding In Metals

(75) Inventor: Charles E. Wickersham, JR., Columbus, OH (US)

Correspondence Address: KILYK & BOWERSOX, P.L.L.C., 400 HOLIDAY COURT, SUITE 102, WARRENTON, VA, 20186, US

(73) Assignee: Cabot Corporation, Boston, MA (US)

(21) Appl. No.: 12/372,230

(22) Filed: Feb. 17, 2009

Related U.S. Application Data
(63) Continuation of application No. 11/059,212, filed on Feb. 16, 2005, now abandoned.
(60) Provisional application No. 60/545,617, filed on Feb. 18, 2004.

(51) Int. Cl. G01N 29/04; C22F 1/00; C22C 27/02; C23C 14/34

(52) U.S. Cl. 702/39; 73/627; 148/400; 148/422; 204/298.13

(57) ABSTRACT

A method for non-destructively detecting the presence of banded regions in a metal is described. The method involves sending an ultrasonic wave into the metal and obtaining reflected signals. The reflected signals are compared with each other to determine variations in signal intensity. A banded region within the metal can be observed as a weaker reflected signal than a reflected backwall signal, thus accurately identifying a location of banding within the metal. Metal articles with a low percent of banding are also described.

This application claims the benefit under 35 U.S.C. §119(e) of prior U.S. Provisional Patent Application No. 60/545,617 filed Feb. 18, 2004, which is incorporated in its entirety by reference herein.

### BACKGROUND OF THE INVENTION

The present invention relates to a method for detecting banding in metals. More particularly, the present invention relates to a method and apparatus for non-destructively detecting banded regions in metals, using ultrasonic equipment. Also, the present invention relates to metal articles, like metal plate, having a low percent banding area such as below 1%.

Banding is a common occurrence in metals worked in forging or rolling operations. A typical practice for yielding a metal sputter target, for example, includes repetitive manipulation of the metal and banding occurs as a result of variations in an amount of working received by individual grains in the metal. When the worked metal is annealed, a recrystallization temperature for the different grains varies with the amount of cold work each grain receives. Those grains receiving a larger amount of cold work will recrystallize at lower temperatures than grains receiving less amounts of cold work. The temperature difference for recrystallization within a single piece of work is what causes banding. Banding can be seen as grains within the metal oriented differently than adjacent grains. In Body Centered Cubic (BCC) metals, as used for sputtering targets, banding is a cosmetic defect and will impart a non-uniform coating in a sputtering process.

Methods for detecting banding in metals primarily relies on visual and/or photographic evaluation. The visual and photographic examination is limited to surface and cross-sectional viewing of the metal sample.

One method of surface evaluation is shown by way of example in FIG. 1. In order to obtain viewable defects, an annealed tantalum plate was first chemically etched with HF acid after vacuum annealing. Here, the banding is appearing as darkened regions having a vertical axis. Rolling of the metal was parallel to the longitudinal axis of the band. This chemical etching is a necessary process to reveal banding on the surface of the metal plate and may degrade its integrity for later use as a sputtering target.

FIG. 2 is an optical micrographic cross-sectional image of a banded metal, illustrating the presence of banding throughout a sample thickness. In this image, the band is horizontally centered between equiaxed regions. The equiaxed regions have a primary orientation of (111). The banded area has a primary orientation of (100). It is further known that the banded region is unrecrystallized. Similar to the surface etching detection method, sectioning of the metal sputtering target compromises its integrity, thereby reducing or removing its further use as a sputtering target.

Accordingly, a need exists in the art to provide a non-destructive method for detecting banding in metals.

### SUMMARY OF THE PRESENT INVENTION

It is therefore a feature of the present invention to provide a method for detecting material variations in a metal.

Another feature of the present invention is to provide a method for detecting banded regions in a metal article, like plate.

A further feature of the present invention is to provide a method for detecting banded regions in a metal plate or other article using ultrasonic signals.

Another feature of the present invention is to provide a method for detecting banded regions in a metal plate or other article by comparing or evaluating reflected ultrasonic signals.

A further feather of the present invention is to provide metals having a very low percent of banded regions or areas.

Additional features and advantages of the present invention will be set forth in part in the description that follows, and in part will be apparent from the description, or may be learned by practice of the present invention. The objectives and other advantages of the present invention will be realized and attained by means of the elements and combinations particularly pointed out in the description and appended claims.

To achieve these and other advantages, and in accordance with the purposes of the present invention, as embodied and broadly described herein, the present invention relates to a method of ultrasonically scanning a metal object to detect material variations in the object. The object preferably has a predominantly oriented equiaxed matrix. Reflected signals are compared with each other to determine any intensity fluctuations between the reflected signals.

The present invention also relates to metal articles, like metal plate, having less than 1% banding in the metal article.

It is to be understood that both the foregoing general description and the following detailed description are exemplary and explanatory only and are intended to provide a further explanation of the present invention, as claimed. The accompanying drawings, which are incorporated in and constitute a part of the application, illustrate various aspects of the present invention and together with the description, serve to explain the principles of the present invention.

### BRIEF DESCRIPTION OF THE DRAWINGS

The present invention may be more fully understood with reference to the accompanying figures. The figures are not to scale and are intended to illustrate exemplary embodiments of the present invention without limiting the scope thereof.

FIG. 1 is a reproduced image of a chemically etched tantalum plate;

FIG. 2 is a cross-sectional image of a banded tantalum plate;

FIG. 3 is a schematic diagram of a method for detecting banding according to one embodiment of the present invention;

FIG. 4 is a schematic diagram of a manual method for detecting banding according to one embodiment of the present invention;

FIG. 5 is a schematic diagram of an automated method for detecting banding according to one embodiment of the present invention;

FIG. 6 is a graphical mapping of manually located banding according to the present invention; and

FIG. 7 is a computer generated mapping of automatically located banding according to the present invention.

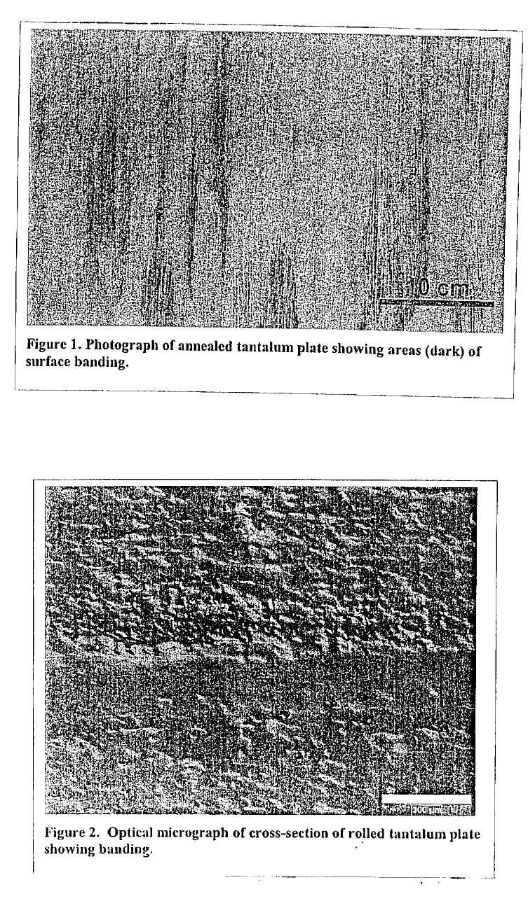

### DETAILED DESCRIPTION OF THE PRESENT INVENTION

A method according to the present invention is to non-destructively detect the presence of banded regions in a metal and includes directing pulsed signals of a predetermined frequency at an incident surface of the metal and obtaining reflected signals. The reflected signals are compared with each other to determine differences in intensity therein.

In the present invention, any portion of the metal or the entire metal can be analyzed using the method of the present invention. Thus, a part of the thickness or the overall thickness of the metal in one location or in all locations of the metal can be analyzed with the present invention. Of course, it is preferred that the method of the present invention be used with the entire surface and thickness of the metal in order to determine any banding or material aberrations in the metal. However, there may be reasons that a portion of the metal is only analyzed using the methods of the present invention and this embodiment is encompassed within the present invention.

In the present invention, any metal can benefit from the method of the present invention. As indicated above, the metal is preferably a BCC type metal. However, non-BCC metals can also benefit with the present invention. Examples of suitable metals include, but are not limited to, tantalum, niobium, titanium, tungsten, copper, cobalt, and alloys thereof.

Furthermore, with respect to the metal, the metal can be an ingot derived metal or can be a powder metallurgy material that is, for instance, consolidated into a metal object such as a metal plate.

With respect to the metal, the metal can be in any shape or size. Examples include, but are not limited to, plates, rods, billets, cylinders, planar shapes, circular shapes, rectangular shapes, sputter targets (bonded, such as to a backing plate and the like or unbonded), hollow cathode magnetron targets, wire, cables, ingots, and any other objects and shapes that are capable of having banding or material aberrations present in the object.

With respect to the detection of banding or other material aberrations, in one example, the metal can have a primary (111) orientation with respect to texture and the present invention is capable of detecting banding of crystal orientations other than (111). For example, a primary (111) orientation of a metal plate may have banding that includes banded regions of (100), and the present invention is capable of detecting this banded region of (100) in the metal plate. Furthermore, the present invention is capable of detecting any other orientation that is inconsistent or non-uniform with the remaining or primary orientation. As another example, the present invention is capable of detecting banded regions of (111) in a primary (100) orientation set forth in a metal plate. Again, any other orientation that is inconsistent or non-uniform with the (100) can be detected by the present invention.

A characteristic feature of metals used in forming sputtering targets is their crystallographic orientation. This crystallographic orientation refers to the primary orientation of the grains subsequent to forming the target. The crystallographic orientation of the metal enables detection of a banded region within a metal structure with the use of ultrasonic technology. Specifically, an acoustic wave travels at a different speed in a banded region than in an equiaxed (unbanded) region of a metal plate because the banded regions in BCC metals typically have a (100) crystallographic orientation parallel to a rolling plane, a high mechanical hardness, and/or an unrecrystallized microstructure. The differentiated (100) texture in the banded region produces a detectable acoustic reflection when subjected to an acoustic wave. This concept is further explained as follows and described in Smithells Metals Reference Book 7^{th} Edition, Edited by E. A. Brandes and G. B. Brook, Butterworth-Heinemann, Oxford, p. 15-6 (1992), incorporated in its entirety by reference herein:

The speed of sound in metals depends upon the metal bulk and sheer modulus with a speed of sound, c given by:

c=\sqrt{[(B+0.75G)/ρ]} Equation 1,

wherein B is the bulk modulus which is 196.3 GPa for tantalum, ρ is the density of the metal (16,600 kg/m³ for tantalum) and G is the shear modulus. The shear modulus depends upon the crystallographic orientation of the metal and varies from 82.6 GPa for <100> tantalum to 102 GPa for <111> tantalum. The values for the shear modulus for tantalum were obtained using the principle elastic compliances and stiffness for tantalum at room temperature and the equation for shear modulus as follows:

1/G=S₄₄−2└(S₁₁−S₁₂)−½S₄₄┘(m²l²+m²n²+l²n²) Equation 2,

wherein m, n and l are the direction cosines between the sound propagation direction and the cubic crystal lattice and S is a tantalum stiffness. For the <100> direction, the directional cosine component is 0 such that G=1/S₄₄, or 82.6 GPa. For the <111> direction, the directional cosine component has a value of 0.334 such that G=102 GPa. Table 1 provides the compliances and stiffness for tantalum as follows:

TABLE 1

| | (10⁻¹² Pa⁻¹) | | (GPa) |
|---|---|---|---|
| S₁₁ | 6.89 | C₁₁ | 262 |
| S₄₄ | 12.1 | C₄₄ | 82.6 |
| S₁₂ | −2.57 | C₁₂ | 156 |

Using the shear modulus for the (100) planes gives the speed of sound in the (100) oriented banded region of 3944 m/sec. Similarly, for the (111) planes, the speed of sound is 4054 m/sec. The change in the speed of sound as the ultrasonic pulse travels from the equiaxed (111) matrix to the banded (100) region results in an ultrasonic reflection from the interface between the banded region and the equiaxed region. The intensity of the reflection, R, is as follows:

R=[(c(111)−c(100))/(c(111)+c(100))]² Equation 3

where c(111) and c(100) are the speed of sound in the (111) and (100) planes, respectively. The speed of sound difference between tantalum (111) and tantalum (100) yields a reflection coefficient of 1.9×10⁻⁴ or a reflected signal intensity of −3.7 dB. This small reflection is detectable in the tantalum plate. Experimental measurements yield an average speed of sound in the tantalum plate of 4080+/−16 m/sec, which agrees with the calculated value obtained from solving Equation 3 above.

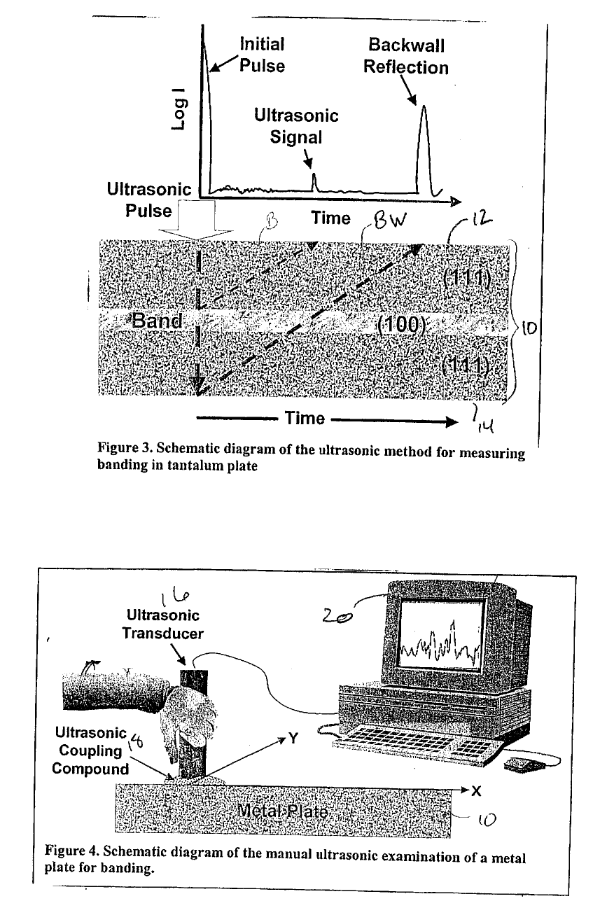

In more detail, and referring now to the FIG. 3, there is shown a schematic diagram of a method for detecting banding in a metal according to one embodiment of the present invention.

The metal plate is shown at element 10 in FIG. 3 and includes a predominantly (111) oriented equiaxed matrix surrounding a predominantly (100) oriented banded layer as shown. For purposes of explaining the present invention, the metal in use will be referred to as a metal plate. It will be appreciated, however, that this language is not intended to limit the metal of the present invention to a plate structure, and any shape suitable for use with the present invention, known now or in the future, is intended to be within the scope of this disclosure.

Continuing, an ultrasonic pulse is shown generally with an arrow and dashed lines and is directed into the metal plate 10 from an ultrasonic transducer 16. The ultrasonic pulse is preferably directed to intersect with the metal plate 10 at an angle which will generate an accurate entry of the pulse wave into the metal plate 10 in order to obtain a reading throughout a thickness of the metal plate 10. The ultrasonic pulse travels from an incident surface 12 to a backwall surface 14 of the metal plate 10. If a banded region, such as region (100), is present within the metal plate 10, the ultrasonic pulse is interrupted at the region of the banding and reflected (as shown at B) at a frequency consistent with the material encountered at the banded region. A signal is also reflected from the backwall surface 14 of the metal plate 10. The reflected signal (BW) from the backwall surface 14 is a stronger reflection signal and characteristic of the backwall surface of the metal plate 10. As also seen from the schematic diagram of FIG. 3, the ultrasonic signal (B) reflected from the banded region (100) occurs prior in time to reflection of the signal (BW) from the backwall surface 14 of the metal plate 10.

With respect to the ultrasonic techniques and equipment that can be used in the methods of the present invention, any device capable of transmitting ultrasonic waves into the metal can be used. Examples include, but are not limited to, transducers manufactured by Krautkramer, Inc. Specific examples of ultrasonic flaw detectors are those available from GE Inspection Technologies, including the USN, USD, USM, USIP, USLT, USPL models as described on GE Inspection Technologies' website (see www.geinspectiontechnolgies.com, incorporated in its entirety by reference herein). In addition, other devices that are capable of directing pulse signals of predetermined frequency can also be used other than ultrasonic devices. Essentially, those skilled in the art readily know the type of devices and set up that can be used to accomplish the methods of the present invention.

The ultrasonic pulse, as directed at the metal plate 10, is typically transmitted at a frequency of 2 to 20 MHz. Other frequencies can be used taking into account the metal being analyzed. More specifically, with use of a tantalum metal plate, an optimum frequency is about 15 MHz. It will be appreciated that the optimum frequency and range provide herein may vary according to a thickness of the metal plate and/or material used for the metal plate. Such variations are intended to be included within the scope of this invention. As the transmitted ultrasonic pulse propagates through the metal plate 10, the acoustic energy thereof is randomly scattered by the equiaxed grains of the metal plate 10. The reflected signal for the (100) banded region and the (111) oriented tantalum matrix is expected to be at about 0.02% of the incident intensity or approximately 4 dB.

Turning now to FIG. 4, there is shown a schematic diagram of a manual method for detecting banding in a metal plate 10 according to the present invention.

The metal plate 10 is supported on a stationary surface for testing purposes. The ultrasonic transducer 16 is manually positioned over the metal plate 10 and an acoustic transmission material such as an ultrasonic coupling compound 18 between the ultrasonic transducer 16 and the metal plate 10 enables acoustic transmissions therebetween. With respect to the coupling compound 18, the conductive compound can be a liquid or gel or other form which is capable of transmitting acoustic signals and permits the practice of the present invention. Examples include, but are not limited to water, aqueous or non-aqueous liquids, or gels and the like. Generally, the amount of coupling compound used is an amount sufficient to provide transmission of the acoustic wave and permit the sending of the acoustic wave, for instance, into the metal.

A processor 20, such as a personal computer or the like, can be directly connected to the ultrasonic transducer 16. The processor 20 can collect and record signal data from the ultrasonic transducer and compares output results from the ultrasonic transducer for display at a user interface. The processor 20 also enables insertion of a gate signal and time domain corresponding to a location within the metal plate 10 where banding is suspected. When a signal is reflected in the gate area that is above the gated noise level, a higher likelihood occurs that the signal may be due to banding. The processor 20 permits any number of inputs, computations, and analysis of data as is known in the art.

The manual method for detecting banding in the metal plate 10 involves user interaction in order to methodically and sequentially scan the surface of the metal plate for banding defects in and throughout the metal plate. Accordingly, multiple readings may be preferable to confirm scanning results. In the event that field testing or an initial scanning is required, however, the manual method of examining a metal plate for banding is highly acceptable.

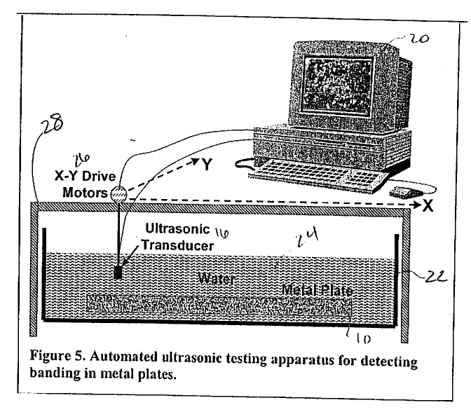

Referring now to FIG. 5, another preferred embodiment of the present invention is shown for scanning a metal plate 10, using an automated ultrasonic testing apparatus.

As shown in FIG. 5, a waterproof container 22 houses the metal plate 10 in a fluid bath 24. The fluid bath may be of any known fluid including water, an electrolyte solution, or similar medium that enables acoustic transmission from the ultrasonic transducer 16 to the metal plate 10.

The automated ultrasonic testing apparatus further includes drive motors 26 interposed between the processor 20 and the ultrasonic transducer 16. The drive motors 26 are supported by a frame 28 or the like above the fluid bath 24 in a manner to enable movement of the transducer 16 in a predetermined grid pattern over a selected part or an entire surface of the metal plate 10. The particular details of the support 28 and the drive motors 26 are not critical to an understanding of the present invention, and may encompass any variety of construction methods or number of motors as needed to enable one of ordinary skill in the art to perform the invention.

In operation, the transducer 16 is moved in a predetermined pattern, such as a grid pattern, over the surface of the metal plate 10, and the reflected signals are collected as a function of the x and y coordinates of the ultrasonic transducer 16. In this manner, a map of the banding within the metal plate 10 can be generated for further manipulation or viewing. Although a grid type scanning pattern of the metal plate 10 is suggested, any appropriate scanning pattern may be used and all are intended to be included within the scope of the invention.

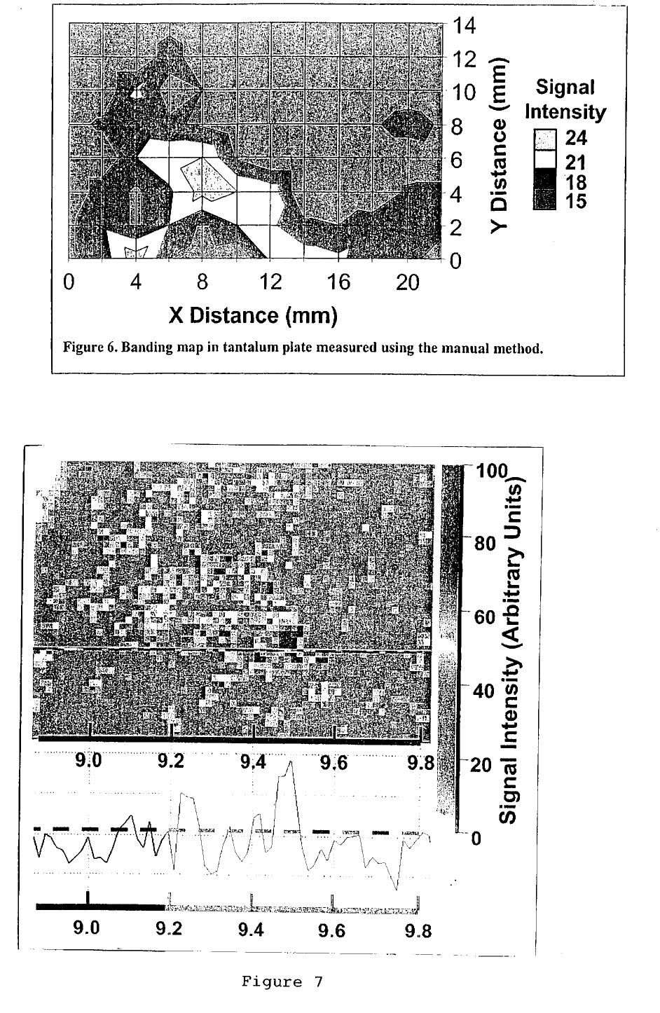

FIG. 6 illustrates results of a manual scanning of the metal plate 10, the metal plate 10 being a rolled and annealed tantalum plate to be used for sputtering. The data shown is a result of multiple manual scanning operations of the plate in order to produce a composite result as shown in the Figure.

FIG. 7 is a computer generated graphical mapping of automatically located banding within a metal plate 10 according to the present invention. Data is similar to that which could be expected from the automatic testing apparatus shown in FIG. 5. The data generated and shown in FIG. 7 is from a rolled tantalum plate to be used as a sputtering target. The ultrasonic beam diameter used to obtain the shown results for the automatic scanning process was 0.8 mm.

As stated above, the present invention also relates to metal articles, such as metal plate, that have a very low amount of banding area in the metal. This percentage of banding area can be determined by the automatic ultrasonic detecting method described herein or by other means, such as neutron diffraction. In more detail, based on the measurement data achieved by a detecting method, a percentage of banding in a portion or overall area of the metal article can be readily determined. As part of the present invention, the present invention relates to metal articles having a total percent banding area of less than 1% (based on the overall area scanned for detection), such as the particular banding percentages set forth below and in Table 2. The metal article can be a BCC metal, such as tantalum, niobium, or tungsten, or other FCC metals such as copper or aluminum or HCP metals such as titanium or cobalt, and alloys thereof. The purity of the metal can be any purity, such as a purity of 95% or higher. Examples of purity ranges include, but are not limited to, 95% to 99.99% pure or higher. Other ranges include 99.5% to 99.999% or higher. This purity can be with respect to metal impurities, but can also include non-metal impurities, such as gas impurities. The metal article also can have any average grain size or average maximum grain size. Average grain size ranges can include 1 micron to 150 microns or higher. Other suitable ranges for average grain size include from 10 microns to 100 microns or higher or from about 10 microns to about 75 microns. The metal article can have any maximum grain size, such as 500 microns, 300 microns, 150 microns, 100 microns, 75 microns, or 50 microns and the like. The metal article can also have any type of texture, for instance, the metal article can have a primary (111) texture or a primary (100) texture or it can have a mixed texture, such as a (111):(100) texture. Further, the material, the purity, grain size, and/or texture, as well as other parameters as described in U.S. Pat. No. 6,348,113 or U.S. Published Patent Application Nos. 2004/0250924; 2004/0141870; 2004/0016635; 2002/0157736; 2002/0072475; or 2002/0011290, can be used or present, in the present invention and all incorporated in their entirety by reference herein. Examples of metal articles, as explained above, include plate, billet, rod, disk, sputter target (bonded to a backing plate or not bonded to a backing plate), and the like. The sputter target can be a hollow cathode magnetron target or a disk target or any other shape. Table 2 below provides detailed measurement data on the percentage of a sample metal plate volume that contains detectable banding obtained, for instance, from an ultrasonic detecting method. The four plates examined in Table 2 are rolled and annealed tantalum plates used for manufacturing sputtering targets. The percent of the banding area can be with respect to the percent banding area only within the thickness of the metal article. Thus, in at least one embodiment, the percent banding area excludes surface banding which is visible before or after the surface is etched. One way to determine the percent banding area, in the case of an ultrasonic detecting method, can be based on the number of pixels which meet a threshold level which correspond to banding. Put another way, the ultrasonic detecting method can be calibrated with a known object having banding, and thus, a threshold number can be obtained which would clearly indicate banding or correlate to banding. After this calibration is achieved, the metal article to be tested can then be subjected to the ultrasonic detection and the number of pixels meeting a threshold number, e.g., signal intensity, would be considered corresponding to a banding area. Upon the particular metal article or portion thereof being measured, the number of pixels meeting the pre-determined threshold would then be considered a detection of a texture banded area and the number of pixels having this banded area can then be compared to the overall number of pixels to determine the percent banding area. The amount of resolution used by the ultrasonic detecting method can be any resolution and, certainly, the higher the resolution, the more precise the percent banding area can be determined. For instance, the resolution can be 5 mm or less, and more preferably 1 mm or less. A resolution that works well is from about 0.5 mm to 1.5 mm with respect to the pixel resolution. The banding area percentages are all below 1%, e.g., from 0.5 to 0.99%, from 0.5 to 0.9%, from 0.5 to 0.85%, from 0.6 to 0.8%. The tantalum plate used to obtain the data in the examples set forth in Table 2 were obtained from an 11 inch diameter electron beam melted tantalum ingot that was forged into a rectangular block with dimensions of 5″×10.5″×30″. The rectangular block was then annealed at 1050° C. for about 10 to 30 minutes. The block was then machined to remove surface defects to a nominal dimension of 4.625″×10.25″×30″. The rectangular annealed block was then rolled in the direction parallel to the 10.25″ dimension so that the 4.625″ thickness is reduced to approximately 1″. The rolling was performed on a 4-high mill with 18 inch nominal working diameter rolls and having a minimum separating force of 2500 tons. The mill gap settings were reduced by 0.090 to 0.110 inch after each pass till a 2 inch nominal plate was obtained and then 0.125 to 0.150 inch after each pass until the desired thickness was reached. A plate of approximated dimensions of 40″×37″ was produced by this rolling operation. The plate was then cut into two equal pieces of dimensions of approximately 20″×37″×1″. Each 20″ wide plate was rotated so that the rolling direction was perpendicular to the original rolling direction and the plate was then rolled to a thickness of 0.36″. The plate was then vacuum annealed at 1050° C. for at least 2 hours. The annealed plate was then flattened and disks of various diameters were cut from the plate.

TABLE 2

| Plate ID | % Banding Area |
|---|---|
| C1A | 0.67 |
| C1B | 0.83 |
| C1D | 0.66 |
| C1D | 0.79 |

With respect to the present invention, one benefit is the ability to analyze metals for banding or other material aberrations in a non-destructive way. This has many advantages since previous methods either did not fully analyze the metal so as to avoid destructive analysis or the metal was cut or a portion removed in order to perform analysis. However, the problem with taking a portion of the metal to analyze it is that the entire thickness and volume of the metal was not analyzed. Thus, if a portion of the metal was removed for analysis, there could very well be banding in another location which was not analyzed. Furthermore, by using a non-destructive and yet accurate detection method, final products such as sputter targets can be analyzed prior to shipment for quality control purposes. There have been problems in the industry by providing sputter targets which have large banding or other material aberrations in the metal causing non-uniform sputtering and other problems. The present invention provides a non-destructive means to detect such banding or other aberrations prior to shipment. Thus, by the present invention, quality control is greatly improved.

It will be appreciated that the method for detecting banding in metals as described herein is equally applicable to metals of all types and containing any known type of defects found in those metals. Further, any suitable acoustic measurement device is expected to be applicable to the method of the present invention. Likewise, ranges of frequencies used for testing the metal samples may be varied according to types of metals used and defects expected to be found within the metal. All such modifications are intended to be within the scope of the present invention.

Applicants specifically incorporate the entire contents of all cited references in this disclosure. Further, when an amount, concentration, or other value or parameter is given as either a range, preferred range, or a list of upper preferable values and lower preferable values, this is to be understood as specifically disclosing all ranges formed from any pair of any upper range limit or preferred value and any lower range limit or preferred value, regardless of whether ranges are separately disclosed. Where a range of numerical values is recited herein, unless otherwise stated, the range is intended to include the endpoints thereof, and all integers and fractions within the range. It is not intended that the scope of the invention be limited to the specific values recited when defining a range.

Other embodiments of the present invention will be apparent to those skilled in the art from consideration of the present specification and practice of the present invention disclosed herein. It is intended that the present specification and examples be considered as exemplary only with a true scope and spirit of the invention being indicated by the following claims and equivalents thereof.

1. A method for non-destructively detecting the presence of banded regions in a metal comprising:
sending an ultrasonic wave into said metal and obtaining reflected signals.

2-3. (canceled)

4. A method for detecting material aberrations in metal comprising:
directing pulsed signals of a predetermined frequency at an incident surface of said metal and obtaining reflected signals.

5. The method of claim 4, wherein said reflected signals are compared with each other to determine any intensity fluctuations in said reflected signals.

6-8. (canceled)

9. The method of claim 4, wherein said metal is a sputter target.

10. (canceled)

11. The method of claim 4, wherein said metal is tantalum or an alloy thereof.

12-14. (canceled)

15. The method of claim 4, wherein said pulsed signals are ultrasonic.

16. The method of claim 4, wherein said pulsed signals are in the range of from about 2 MHz to about 20 MHz.

17-19. (canceled)

20. The method of claim 4, wherein said aberration is a banded region in said metal.

21. The method of claim 4, wherein said aberration is a banded region substantially parallel to a planar surface of said metal.

22. The method of claim 4, wherein said aberration is inconsistent in grain orientation with a predominant grain orientation of said metal.

23-24. (canceled)

25. The method of claim 4, wherein detection of aberrations in said metal is throughout a volume of said metal.

26. (canceled)

27. The method of claim 4, wherein reflected signal intensity corresponds to variations in crystallographic orientations of said metal.

28. The method of claim 4, wherein said pulsed signals are generated by an ultrasonic transducer.

29. The method of claim 28, further comprising:
providing an acoustic transmission medium between said ultrasonic transducer and said metal;
selectively moving said ultrasonic transducer with respect to a surface of said metal; and
providing a processor in communication with said transducer for at least collecting transducer data.

30. The method of claim 29, further comprising:
inserting a gate signal in said processor corresponding to a potential aberration in said metal;
processing said reflected signals relative to said gate signal; and
analyzing variations of reflected signals in a region of said gate signal in order to determine banding.

31-34. (canceled)

35. The method of claim 29, wherein said acoustic transmission medium is a coupling compound between said ultrasonic transducer and said metal.

36. The method of claim 29, wherein said acoustic transmission medium is a fluid bath.

37. The method of claim 29, further comprising:
mapping received signals to record a pattern of signals.

38. A device for automatically scanning a metal to detect banding, comprising:
a fluid bath having said metal immersed therein;
an ultrasonic transducer suspended in said fluid bath and spaced apart from said metal, said ultrasonic transducer sending signals into said metal and obtaining reflected signals therefrom;
means for moving said ultrasonic transducer in a scanning pattern over said metal; and
a processor connected to said ultrasonic transducer for operatively collecting and comparing reflected signal data and outputting a readable result.

39. A device for automatically scanning a metal to detect banding, comprising:
an acoustic transducer operatively positioned with respect to said metal;
means for moving said acoustic transducer in a scanning pattern over said metal; and
a processor connected to said acoustic transducer for collecting and comparing reflected acoustic signal data and outputting a readable result.

40-43. (canceled)

44. A metal article having a primary texture, wherein said metal article has a percent texture banding area of less than 1% that is inconsistent or non-uniform with respect to the primary texture present in said metal article.

45. The metal article of claim 44, wherein said metal article is a BCC metal article.

46. The metal article of claim 44, wherein said metal article is a tantalum article, niobium article, or alloys containing tantalum, niobium, or both.

47. The metal article of claim 46, wherein said metal article has at least one of the following characteristics:
a) a purity of at least 95%,
b) an average grain size of 150 microns or less.

48. The metal article of claim 46, wherein said primary texture is a primary (111) texture.

49. The metal article of claim 48, wherein said percent texture banding area is with respect to (100) texture banding.

50. The metal article of claim 46, wherein said metal article has a primary mixed (111):(100) texture.

51. (canceled)

52. The metal article of claim 46, wherein said metal article is a sputter target that is bonded to a backing plate.

53. (canceled)

54. The metal article of claim 46, wherein percent banding area is from 0.5 to 0.99%.

55. (canceled)

56. The metal article of claim 46, wherein said percent banding area is from 0.5 to 0.85%.

57-58. (canceled)

59. The metal article is claim 46, wherein said tantalum article is a sputter target bonded to a backing plate.
